(19) United States
(12) Patent Application Publication
(10) Pub. No.: US 2014/0339690 A1
(43) Pub. Date: Nov. 20, 2014

(54) Elimination of Die-Top Delamination

(71) Applicant: Infineon Technologies AG, Neubiberg (DE)

(72) Inventors: Swee Guan Chan, Melaka (MY); Kong Yang Leong, Muar (MY); Mei Yong Wang, Air Keroh (MY); Heinrich Koerner, Bruckmuehl (DE)

(21) Appl. No.: 13/897,620

(22) Filed: May 20, 2013

(51) Int. Cl. H01L 23/00

(52) U.S. Cl. CPC H01L 24/49; H01L 24/85
USPC 257/666; 438/123; 257/737; 438/121

(57) ABSTRACT

An integrated-circuit module includes an integrated-circuit device having a first surface and a plurality of bond pads disposed on the first surface. The module further includes metallic bond wires or metallic ribbons, which are attached between respective ones of a first subset of the bond pads and a package substrate or leadframe, such that a second subset of the bond pads are not attached to either a package substrate or leadframe. A metallic stud bump is affixed to each of one or more of the second subset of the bond pads. The integrated-circuit module further comprises a molding compound that contacts at least the first surface of the integrated-circuit device and substantially surrounds the bond wires or ribbon wires and the metallic stud bumps.

### TECHNICAL FIELD

The present application relates to integrated-circuit modules, and in particular to techniques for reducing or eliminating delamination of molding compound from an integrated-circuit device in an integrated-circuit module.

### BACKGROUND

Integrated-circuit devices are packaged in a variety of different package types, in several form factors. One popular package, for example, is the plastic quad flat package (QFP), which has so-called gull-wing leads extending from the four sides of the generally planar, rectangular package.

FIG. 1 is a cross-sectional view of an integrated-circuit module using one such package. As shown in the figure, an integrated-circuit device 110 (or “die”) is bonded to a package substrate 115, e.g., using an epoxy material. The package substrate may be the die paddle portion of a lead-frame, for example. Wire bonds 130 are attached from bond pads on the device 110 to attachment points on leads 120. The device 110 and the package substrate are then over-molded with a plastic molding compound material 140, which, after curing, forms the plastic package body. As seen in FIG. 1, the molding compound 140 may completely encapsulate the package substrate, for some package types. In other package types, the bottom part of the package substrate may be exposed. This approach may be particularly suitable for power devices, where the package substrate serves as a heat sink.

FIG. 2 illustrates another example of an integrated-circuit module, in this case utilizing a ball-grid array (BGA) packaging technique. Device 110 is mounted on a package substrate 215, where package substrate 215 includes a top-side metallization layer that includes device-mounting area 220 and various conductive leads 230. Bond wires 130 are attached from bond pads 145 on the top surface of device 110 to bonding locations 225 on the top surface of the package substrate 215. Once again, a molding compound 140 is used, in this case to overmold the device 110 and the top side of the package substrate 215.

The conductive leads on the top side of package substrate 215 are connected to bottom-side interconnects 235, using conductive vias (not shown). Solder balls 240 are formed on the bottom-side interconnects 235. The package substrate 215 may be a multi-layer ceramic substrate with multiple metallization layers and conductive vias between metallization layers, in some embodiments. In others, the package substrate 215 may utilize thin-film technology to form one or more redistribution layers that connect the conductive leads on the top side of package substrate 215 to the solder balls 240.

The molding compound 140 is typically an epoxy resin, which may include one or more flame retardant materials, cross-linking agents, inhibitors, and mold-release agents. The primary purposes of the molding compound are to provide physical protection of the fragile integrated-circuit device and the module's internal connections, including the bond wires, to electrically insulate the integrated-circuit device and the internal connections, and to provide moisture resistance, so that external moisture does not damage the module or impair its performance.

To achieve these purposes, it is important that the molding compound maintain good and consistent adhesion to the surface of the device, the package substrate, and the leads, over a wide range of environmental conditions. However, delamination of the molding compound from the surface of the integrated-circuit device is a well-known problem. It has been observed that poor adhesion of molding compound is particularly problematic with respect to surface features plated with a noble metal, such as gold. Once delamination begins, e.g., in the region of a gold-plated surface feature, it can spread to other portions of the device and/or module. Accordingly, improved techniques to reduce or eliminate delamination at the surface of an integrated-circuit device are needed.

### SUMMARY

Embodiments of the present invention include integrated-circuit modules and methods for producing such modules. According to an example embodiment, an integrated-circuit module comprises an integrated-circuit device having a first surface and a plurality of bond pads disposed on the first surface. The module further includes metallic bond wires or metallic ribbons, which are attached between respective ones of a first subset of the bond pads and a package substrate or leadframe, such that a second subset of the bond pads are not attached to either a package substrate or leadframe. A metallic stud bump is affixed to each of one or more of the second subset of the bond pads. The integrated-circuit module further comprises a molding compound that contacts at least the first surface of the integrated-circuit device and substantially surrounds the bond wires or ribbon wires and the metallic stud bumps.

In an example method of fabricating an integrated-circuit module, an integrated-circuit device having a first surface and a plurality of bond pads disposed on the first surface is provided. Metallic bond wires or metallic ribbons are attached between respective ones of a first subset of the bond pads and a package substrate or leadframe, such that a second subset of the bond pads are not attached to either a package substrate or leadframe. A metallic stud bump is affixed to each of one or more of the second subset of the bond pads, and a molding compound is disposed on the integrated-circuit device so that the molding compound contacts the first surface and substantially surrounds the bond wires or ribbon wires and the metallic stud bumps.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined, unless they exclude each other. Embodiments are depicted in the drawings and are detailed in the description which follows.

FIG. 1 illustrates a sectional side view of an integrated-circuit module having device bond pads bonded to leads of a leadframe.

FIG. 2 is a sectional side view of an integrated-circuit module having device bond pads bonded to leads on a substrate.

FIG. 3 is a top view illustrating used and unused bond pads on the surface of an integrated-circuit device.

FIG. 4 shows details of an example stud bump on an unused bond pad of an integrated-circuit device.

FIG. 5 is a cross-sectional view of a packaged integrated-circuit module incorporating stud bumps on unused bond pads.

FIG. 6 illustrates a method of manufacturing a module.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

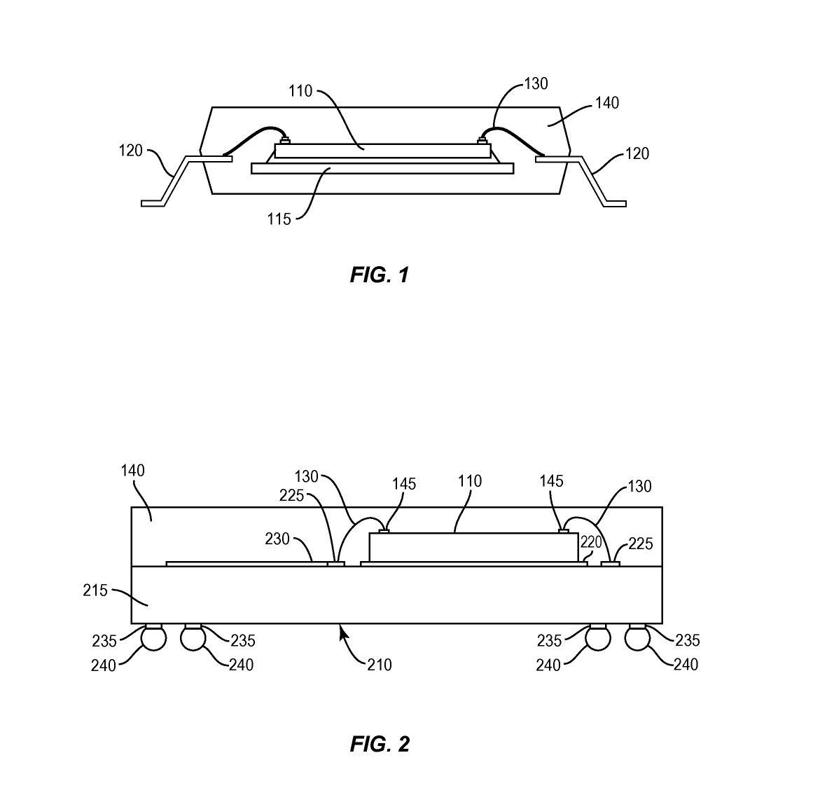

In the discussion that follows, various embodiments of the present invention are described in the context of an integrated-circuit module in which bond wires or ribbon bonds are attached between bond pads on one or more integrated-circuit devices and a package substrate or leadframe. While FIGS. 1 and 2 illustrate two example package types, it will be appreciated that the techniques disclosed herein are not limited to those package types, but may be applied to a wide variety of package technologies and package types, including, for example, the QFP package, the Quad-Flat No-lead (QFN) package, the Ball Grid Array (BGA) package, and others.

When an integrated-circuit device is packaged, it is often the case that one or more bond pads on the active surface of the integrated-circuit device are unused, in that they are not attached to any of the leads or interconnects of the package. This can be for several reasons. For instance, one or more bond pads may be only used during wafer-level or die-level testing, prior to packaging of the device. In some cases, an integrated-circuit device may be designed to support a number of customer applications or configurations, where only a subset of the bond pads are need for any particular application or configuration. For instance, a particular integrated-circuit device may be designed to support several communications interfaces, but can be packaged so that fewer than all of those communications interfaces are connected to package leads for any given customer-specific version.

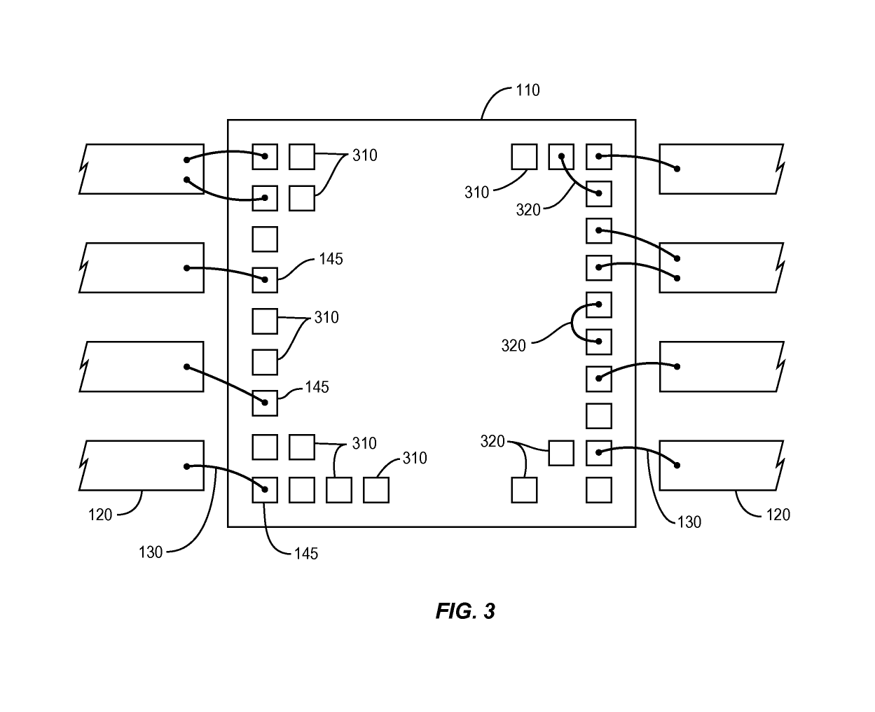

FIG. 3 illustrates an example configuration of an integrated-circuit module in which a first subset of bond pads 145 on an integrated-circuit device 110 are “used,” in the sense that they are attached with bond wires 130 to connection points 120 on a lead frame or package substrate. A second subset of bond pads 310 are “unused,” in that they are not attached to the lead frame or to leads on a package substrate. It should be appreciated that the example shown in FIG. 3 is quite simple—more complex modules may include devices that have tens or hundreds of bond pads, with a substantial fraction of those bond pads being unused.

As noted above, delamination of an encapsulating molding compound from the surface of an integrated-circuit is a well-known problem, and can result in damage to a device or to decreased device performance. It has been observed that some delamination problems are the result of poor adhesion between the molding compound and surface features plated with a noble metal, such as gold. More particularly, the inventors have observed that delamination can begin at and around unused bond pads on the surface of an integrated-circuit device and can spread from there to other regions. The delamination can cause severe problems, e.g., when it puts stress on bond wires connected to used bond pads.

One possible approach to mitigate this problem is to cover the unused pads, e.g., with a passivation layer or a thin insulating layer, such as a polyimide film. However, this approach can increase the module cost, as it requires an extra mask step and an extra process step. Further, this technique maps poorly to the approach whereby a single integrated-circuit device is designed for use in several different customer applications/configurations, since the subset of unused pads may differ from one configuration to another, thus requiring a different mask set or process step for each configuration. Once a pad is covered with a passivation layer, the device can no longer be used in any configuration that requires the use of that pad.

Other possible approaches are to change the metallization of all the bond pads and/or to change the composition of the molding compound, to achieve better adhesion between the molding compound and the bond pads. However, either of these changes may have unintended consequences, e.g., with respect to the adhesion of bond wires to the bond pads or with respect to the molding compound's moisture resistance, thermal properties, etc.

Another approach, which may be applicable to at least some of the unused bond pads, is to wire bond each unused bond to another, nearby, unused bond pad. The bond wires may be copper bond wires, for example, attached to the bond pads with nailhead bonds and/or wedge bonds. Examples of this approach are shown in FIG. 3, where bond wires 320 are attached between pairs of nearby bond pads. A related approach is to wire bond one or more of the unused bond pads to an unused portion of a leadframe, or to an unused bonding area on a package substrate. Either of these approaches reduces the surface area of the bond pad that is exposed to the molding compound, improving the adhesion of the molding compound in the vicinity of the bond pad. These approaches, however, may be of limited use, depending on the layout of the unused bond pads and the overall density of the wire bonds that connect used bond pads to the lead frame and/or package substrate of the integrated-circuit module. Further, bonding one unused bond pad to another may not be feasible if either or both of the unused bond pads are connected to electrically active portions of the integrated circuit.

Another approach is to affix a metallic “stud bump” to one or more of the unused bond pads. This approach also reduces the portion of the unused bond pad that is exposed to the molding compound. This approach also provides a structure extending above the surface of the integrated-circuit device that can be surrounded by molding compound, thus tending to interlock the integrated-circuit device surface and the molding compound. Both of these effects improve adhesion of the molding compound at and around the bond pad. Further, this approach does not suffer from the disadvantages of the previous approaches.

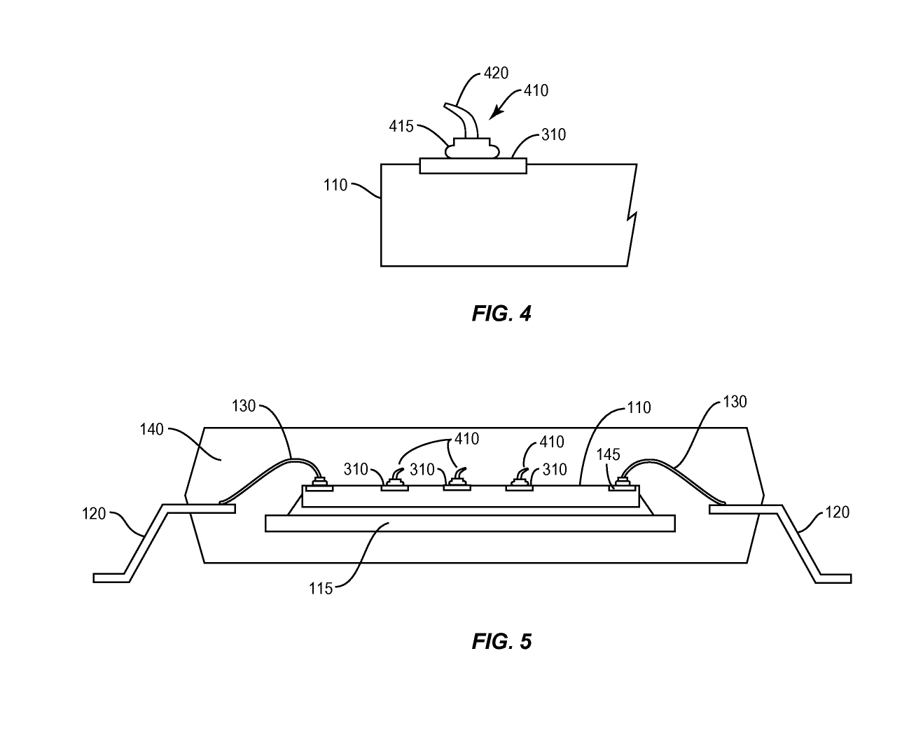

One example of this technique is shown in FIG. 4, which illustrates a metallic stud bump 410 that comprises a nailhead bond 415, affixed to an unused bond pad 310, and a short wire segment 420, which has been severed proximate the nailhead bond. This severing of the wire segment may be accomplished by cutting or pinching off the wire. Further, while a nailhead bond 415 is shown in FIG. 4, other bonding techniques may be used.

It will be appreciated that stud bump 410 may be formed using the same metallic bond wire material and the same tools used to connect used bond pads to a lead frame or package substrate, such as a copper or aluminum wire. Other bond wire materials and/or tools may be used, of course. However, good adhesion of the metallic stud bump 410 to the unused bond pad remains important.

FIG. 5 illustrates an example of an integrated-circuit module that incorporates the “stud bump” approach described above. As was the case in FIG. 1, the illustrated integrated-circuit module includes an integrated-circuit device 110, affixed to a package substrate 115. Used bond pads 145 on the integrated-circuit device 110 are attached to package leads 120, with wire bonds 130. The integrated-circuit device 110 in the module of FIG. 5 is encapsulated with a molding compound layer 140, as was the case in the module pictured in FIG. 1. In this case, however, several stud bumps 410 are attached to unused bond pads 310. As discussed above, this improves adhesion of the molding compound to the integrated-circuit device 110 in the vicinity of the stud bumps, reducing or eliminating delamination.

It should be noted that improved adhesion and reduced delamination can be achieved without putting a stud bump on every unused bond pad. This is particularly true when a large number of unused bond pads are close together. In some embodiments, the stud bumps may be applied to only a subset of unused bond pads, e.g., according to a predetermined pattern or rule. For example, a stud bump may be applied to every second unused bond pad, in some embodiments. In other embodiments, a subset of the unused bond pads may be randomly selected, with stud bumps applied only to the randomly selected bond pads.

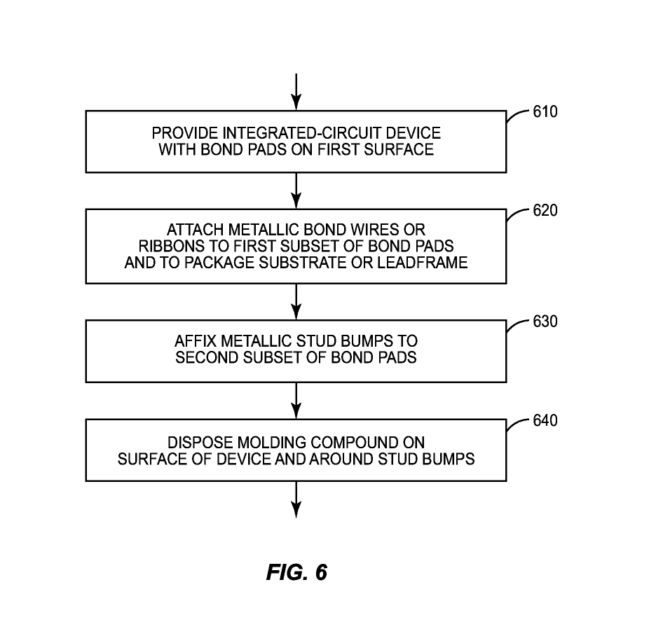

FIG. 6 illustrates a method of manufacturing an integrated-circuit module according to some of the techniques discussed above. As seen at block 610, the illustrated method begins with the providing of a an integrated-circuit device having a first surface and a plurality of bond pads disposed on the first surface. As shown at block 620, metallic bond wires or metallic ribbons are attached between respective ones of a first subset of the bond pads and a package substrate or leadframe, such that a second subset of the bond pads are not attached to either a package substrate or leadframe. Further, as shown at block 630, a metallic stud bump is affixed to each of one or more of the second subset of the bond pads. Finally, as seen at block 640, a molding compound is disposed on the integrated-circuit device so that the molding compound contacts the first surface and substantially surrounds the bond wires or ribbon wires and the metallic stud bumps.

In some embodiments, as discussed above, affixing a metallic stud bump to each of one or more of the second subset of the bond pads comprises affixing a nail-head bond to each one of the second subset of bond pads. In some of these embodiments, a wire segment extending from the nailhead bond is severed, proximate the nailhead bond. As suggested above, this severed wire segment effectively provides a “hook,” interlocking the surface of the integrated-circuit device to the molding compound.

In some embodiments, affixing a metallic stud bump to each of one or more of the second subset of the bond pads comprises affixing a metallic bond wire to each of two of the second subset of the bond pads, thus connecting a pair of unused bond pads with a bond wire.

In some embodiments, an exposed surface of each of the second subset of the bond pads comprises a noble metal, while the metallic stud bumps substantially consist of copper or aluminum. In some embodiments, all of the bond pads receiving stud bumps are electrically unused by the integrated-circuit device.

In some embodiments, every unused bond pad receives a stud bump. In others, fewer than all of the unused bond pads receive stud bumps. In some embodiments, for example, a metallic stud bump is affixed to alternating ones of the second subset of bond pads. In other embodiments, a metallic stud bump is affixed to randomly selected ones of the second subset of bond pads.

Terms such as “same”, “match” and “matches” as used herein are intended to mean identical, nearly identical, or approximately so that some reasonable amount of variation is contemplated without departing from the spirit of the invention. The term “constant” means not changing or varying, or changing or varying slightly so that some reasonable amount of variation is contemplated without departing from the spirit of the invention. Further, terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. The description of various techniques provided herein is intended to cover any adaptations or variations of the specific embodiments discussed herein. Therefore, it is intended that the present invention be limited only by the claims attached hereto and the equivalents thereof.

What is claimed is:

1. An integrated-circuit module, comprising:
an integrated-circuit device having a first surface and a plurality of bond pads disposed on the first surface;
metallic bond wires or metallic ribbons attached between respective ones of a first subset of the bond pads and a package substrate or leadframe, such that a second subset of the bond pads are not attached to either a package substrate or leadframe;
a metallic stud bump affixed to each of one or more of the second subset of the bond pads; and
a molding compound contacting the first surface and substantially surrounding the bond wires or ribbon wires and the metallic stud bumps.

2. The integrated-circuit module of claim 1, wherein one or more of the metallic stud bumps comprise a nail-head bond affixed to a corresponding one of the second subset of the bond pads.

3. The integrated-circuit module of claim 2, wherein the one or more of the metallic stud bumps further comprise a wire segment severed proximate the nailhead bond.

4. The integrated-circuit module of claim 1, wherein the metallic stud bumps comprise a metallic bond wire affixed to each of two of the second subset of the bond pads.

5. The integrated-circuit module of claim 1, wherein an exposed surface of each of the second subset of the bond pads comprises a noble metal, and wherein the metallic stud bumps substantially consist of copper or aluminum.

6. The integrated-circuit module of claim 1, wherein the second subset of bond pads consists of bond pads that are electrically unused by the integrated-circuit device.

7. The integrated-circuit module of claim 1, wherein the second subset of bond pads comprises all bond pads on the integrated-circuit device other than the first subset of bond pads, and wherein a metallic stud bump is affixed to every one of the second subset of bond pads.

8. The integrated-circuit module of claim 1, wherein the second subset of bond pads comprises all bond pads on the integrated-circuit device other than the first subset of bond pads, and wherein a metallic stud bump is affixed to alternating ones of the second subset of bond pads.

9. A method for fabricating an integrated-circuit module, the method comprising:
providing an integrated-circuit device having a first surface and a plurality of bond pads disposed on the first surface;
attaching metallic bond wires or metallic ribbons between respective ones of a first subset of the bond pads and a package substrate or leadframe, such that a second subset of the bond pads are not attached to either a package substrate or leadframe;
affixing a metallic stud bump to each of one or more of the second subset of the bond pads; and
disposing a molding compound on the integrated-circuit device so that the molding compound contacts the first surface and substantially surrounds the bond wires or ribbon wires and the metallic stud bumps.

10. The integrated-circuit module of claim 9, wherein affixing a metallic stud bump to each of one or more of the second subset of the bond pads comprises affixing a nail-head bond to a corresponding one of the second subset of the bond pads.

11. The integrated-circuit module of claim 10, wherein affixing a metallic stud bump to each of one or more of the second subset of the bond pads further comprises severing, proximate the nailhead bond, a wire segment extending from the nailhead bond.

12. The integrated-circuit module of claim 9, wherein affixing a metallic stud bump to each of one or more of the second subset of the bond pads comprises affixing a metallic bond wire to each of two of the second subset of the bond pads.

13. The integrated-circuit module of claim 9, wherein an exposed surface of each of the second subset of the bond pads comprises a noble metal, and wherein the metallic stud bumps substantially consist of copper or aluminum.

14. The integrated-circuit module of claim 9, wherein the second subset of bond pads consists of bond pads that are electrically unused by the integrated-circuit device.

15. The integrated-circuit module of claim 9, wherein the second subset of bond pads comprises all bond pads on the integrated-circuit device other than the first subset of bond pads, and wherein affixing a metallic stud bump to each of one or more of the second subset of the bond pads comprises affixing a metallic stud bump to every one of the second subset of bond pads.

16. The integrated-circuit module of claim 9, wherein the second subset of bond pads comprises all bond pads on the integrated-circuit device other than the first subset of bond pads, and wherein affixing a metallic stud bump to each of one or more of the second subset of the bond pads comprises affixing a metallic stud bump to alternating ones of the second subset of bond pads.

17. The integrated-circuit module of claim 9, wherein the second subset of bond pads comprises all bond pads on the integrated-circuit device other than the first subset of bond pads, and wherein affixing a metallic stud bump to each of one or more of the second subset of the bond pads comprises affixing a metallic stud bump to randomly selected ones of the second subset of bond pads.
